(19) United States
(12) Patent Application Publication
(10) Pub. No.: US 2006/0208283 A1
(43) Pub. Date: Sep. 21, 2006

(54) Semiconductor device

(75) Inventors: Yoshiro Shimojo, Yokohama-shi (JP); Iwao Kunishima, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/217,295

(22) Filed: Sep. 2, 2005

(30) Foreign Application Priority Data
Mar. 17, 2005 (JP) 2005-077352

(51) Int. Cl. H01L 27/10

(52) U.S. Cl. 257/208; 257/390

(57) ABSTRACT

A semiconductor device includes a plurality of first word lines which extend in a first direction, a plurality of second word lines which extend in a direction orthogonal to the first direction, a plurality of selection circuits which are provided at intersections of the first word lines and the second word lines, and each of which includes a first transistor and a second transistor which are connected in series, the first transistor having a gate electrode connected to one of the first word lines, and the second transistor having a gate electrode connected to one of the second word lines.

### CROSS-REFERENCE TO RELATED APPLICATIONS

This application is based upon and claims the benefit of priority from prior Japanese Patent Application No. 2005-077352, filed Mar. 17, 2005, the entire contents of which are incorporated herein by reference.

### BACKGROUND OF THE INVENTION

1. Field of the Invention

The present invention relates to a semiconductor device, and in particular, to a semiconductor device including metal oxide semiconductor (MOS) transistors having vertical channels.

2. Description of the Related Art

Development in semiconductor manufacturing technology has increased the speeds of semiconductor devices and their degrees of integration. This has made it necessary to reduce the sizes of elements used in semiconductor devices and to further increase the degree of integration.

For example, in dynamic random access memory (DRAM), a plurality of memory cells are connected to a plurality of word lines and plural pairs of bit lines BL and /BL which are arranged in lattice form. A planar transistor is used to select any of capacitors provided in the memory cells and serving as storage elements. DRAM uses, for example, a folded bit line layout (in which the pairs of bit lines BL and /BL connected to one sense amplifier are arranged in the same direction with respect to the sense amplifier).

The folded bit line layout is resistant to a local variation in process. However, the capacitors, serving as storage elements, are very sparsely arranged. This is because the increased density of the capacitors causes both of capacitors connected to the paired bit lines BL and /BL to be electrically connected to the bit lines when any of the word lines WL is turned on. That is, all the capacitors on the one word line are electrically connected to the bit lines. Accordingly, the increase in the degree of integration is limited.

As a related technique of this kind, a method for manufacturing a vertical transistor (Documents 1 and 2) has been disclosed.

Document 1: J. M. Hergenrother et al., The vertical replacement-gate (VRG) MOSFET, Solid-State Electronics 46 (2002), p 939-950

Document 2: H. Takato et al., High Performance CMOS Surrounding Gate Transistor (SGT) for Ultra High Density LSIs, Tech. Dig. Int. Electron Devices Meet., 1988, p 222

### BRIEF SUMMARY OF THE INVENTION

According to a first aspect of the present invention, there is provided a semiconductor device comprising: a plurality of first word lines which extend in a first direction; a plurality of second word lines which extend in a direction orthogonal to the first direction; a plurality of selection circuits which are provided at intersections of the first word lines and the second word lines, and each of which includes a first transistor and a second transistor which are connected in series, the first transistor having a gate electrode connected to one of the first word lines, and the second transistor having a gate electrode connected to one of the second word lines.

According to a second aspect of the present invention, there is provided a semiconductor device comprising: a first source/drain layer; a first gate electrode provided above the first source/drain layer so as to extend in a first direction and having a first opening; a first gate insulating film provided so as to cover a side surface of the first opening; a first base layer provided on the first source/drain layer and on a side surface of the first gate insulating film and being of a first conductivity type; a second source/drain layer provided above the first gate electrode and on the first base layer; a second gate electrode provided above the second source/drain layer so as to extend in a direction orthogonal to the first direction and having a second opening; a second gate insulating film provided so as to cover a side surface of the second opening; a second base layer provided on the second source/drain layer and on a side surface of the second gate insulating film and being of the first conductivity type; and a third source/drain layer provided above the second gate electrode and on the second base layer.

According to a third aspect of the present invention, there is provided a semiconductor device comprising: a first source/drain layer; a first gate electrode provided above the first source/drain layer so as to extend in a first direction and having a first opening; a first gate insulating film provided so as to cover a side surface of the first opening; a first base layer provided on the first source/drain layer and on a side surface of the first gate insulating film; a second source/drain layer provided above the first gate electrode and on the first base layer; a contact layer provided on the second source/drain layer; a third source/drain layer provided on the contact layer; a second gate electrode provided above the third source/drain layer so as to extend in a direction orthogonal to the first direction and having a second opening; a second gate insulating film provided so as to cover a side surface of the second opening; a second base layer provided on the third source/drain layer and on a side surface of the second gate insulating film; and a fourth source/drain layer provided above the second gate electrode and on the second base layer.

According to a fourth aspect of the present invention, there is provided a semiconductor device comprising: a semiconductor substrate; a first gate electrode provided on the semiconductor substrate via a first gate insulating film so as to extend in a first direction; a first and second source/drain layers provided on opposite sides of the first gate electrode and in the semiconductor substrate; a contact layer provided on the first source/drain layer; a third source/drain layer provided on the contact layer; a second gate electrode provided above the third source/drain layer so as to extend in a direction orthogonal to the first direction and having a opening; a second gate insulating film provided so as to cover a side surface of the opening; a base layer provided on the third source/drain layer and on a side surface of the second gate insulating film; and a fourth source/drain layer provided above the second gate electrode and on the base layer.

### BRIEF DESCRIPTION OF THE SEVERAL VIEWS OF THE DRAWING

FIG. 1 is a circuit diagram of a semiconductor device according to a first embodiment of the present invention;

FIG. 2 is a layout diagram of a semiconductor device according to the first embodiment of the present invention;

FIG. 3 is a sectional view taken along line III-III shown in FIG. 2;

FIG. 4 is a sectional view showing an example of a method for manufacturing a semiconductor device shown in FIG. 3;

FIG. 5 is a sectional view showing a part of the method for manufacturing a semiconductor device which is continued from FIG. 4;

FIG. 6 is a sectional view showing a part of the method for manufacturing a semiconductor device which is continued from FIG. 5;

FIG. 7 is a sectional view showing a part of the method for manufacturing a semiconductor device which is continued from FIG. 6;

FIG. 8 is a plan view of the semiconductor device shown in FIG. 7;

FIG. 9 is a sectional view showing a part of the method for manufacturing a semiconductor device which is continued from FIG. 7;

FIG. 10 is a sectional view showing a part of the method for manufacturing a semiconductor device which is continued from FIG. 9;

FIG. 11 is a sectional view showing a part of the method for manufacturing a semiconductor device which is continued from FIG. 10;

FIG. 12 is a sectional view of a semiconductor device according to a second embodiment of the present invention; and

FIG. 13 is a sectional view of a semiconductor device according to a third embodiment of the present invention.

### DETAILED DESCRIPTION OF THE INVENTION

Embodiments of the present invention will be described below with reference to the drawings. In the description below, elements having the same functions and configurations are denoted by the same reference numerals. Duplicate descriptions will be given only when required.

(First Embodiment)

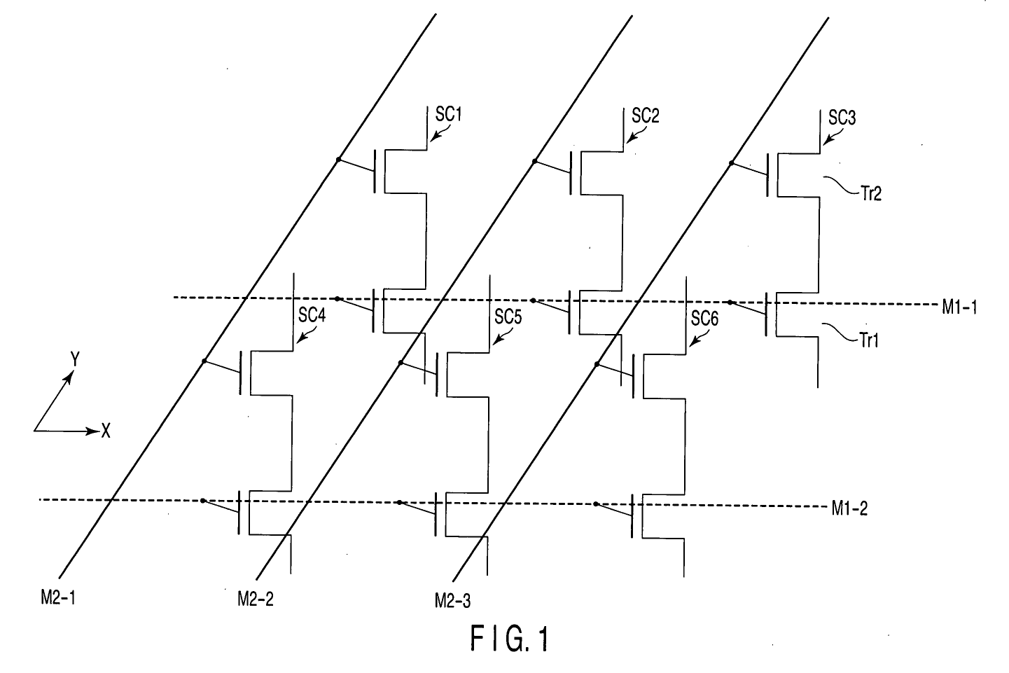

FIG. 1 is a circuit diagram of a semiconductor device according to a first embodiment of the present invention.

The semiconductor device comprises a plurality of first word lines M1-0 to M1-n, and a plurality of second word lines M2-0 to M2-m. The plurality of first word lines M1-0 to M1-n extend in an X direction.

The plurality of second word lines M2-0 to M2-m are arranged above the word lines M1-0 to M1-n. The plurality of second word lines M2-0 to M2-m are arranged so as to extend, for example, in a Y direction orthogonal to the X direction. FIG. 1 shows, by way of example, two first word lines M1-1 and M1-2, and three second word lines M2-1, M2-2 and M2-3.

Selection circuits SC are provided, respectively, at the intersections of the first word lines M1 and the second word lines M2. Only six (=2×3) selection circuits SC1 to SC6 are illustrated in FIG. 1.

Each selection circuit comprises two transistors Tr1 and Tr2, which are connected in series. More precisely, the drain regions of the transistors Tr1 and Tr2 are connected to each other. The transistors Tr1 and Tr2 are, for example, n-channel MOS transistors.

The gate electrode of the transistor Tr1 is connected to a first word line M1. The gate electrode of the transistor Tr2 is connected to a second word line M2.

How the semiconductor device thus configured operates will be described. To supply a feedthrough current to any selection circuit (that is, to activate any selection circuit), the word lines M1 and M2 are set to high level (high potential).

Assume that a feedthrough current should flow in, for example, the selection circuit SC5. In this case, the first word line M1-2 and the second word line M2-2 are set to high level. At this time, one or both of the first word line M1 and second word line M2 connected to each of the other selection circuits (SC1, SC2, SC3, SC4 and SC6) are at a low level (low potential). Hence, no feedthrough currents flow in the selection circuits SC1, SC2, SC3, SC4 and SC6.

Thus, only one of the section circuits SC can be opened in the semiconductor device according to the first embodiment.

The transistors Tr1 and Tr2 in each selection circuit are not limited to n-channel MOS transistors. They may be p-channel MOS transistors, instead. If this is the case, to activate any selection circuit SC, the potential of the first word line and the second word line, which are connected to this selection circuit SC, is changed from a high level to a low level.

Moreover, the two transistors of each selection circuit may be an n-channel MOS transistor and a p-channel MOS transistor, respectively. In this case, two word lines connected to the gate electrodes of the n- and p-channel MOS transistors, respectively, are set at a high potential and a low potential, respectively, thereby to activate the selection circuit SC.

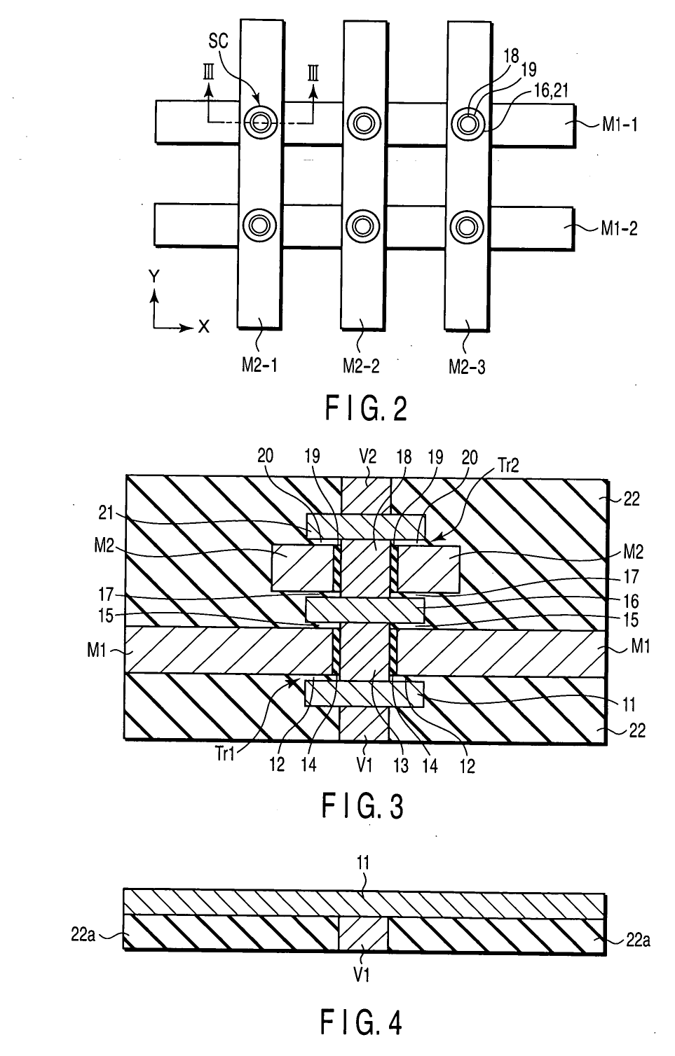

The semiconductor device of FIG. 1 will be described in terms of its structure. FIG. 2 is a layout diagram of a semiconductor device according to the first embodiment of the present invention.

A plurality of first word lines M1-0 to M1-n are arranged above a principal surface of a substrate (not shown). The plurality of first word lines are arranged in an X direction.

A plurality of second word lines M2-0 to M2-m are arranged above the first word lines M1. A plurality of second word lines M2 are arranged so as to extend in a Y direction orthogonal to the X direction. FIG. 2 shows, by way of example, the two first word lines M1-1 and M1-2 and the three second word lines M2-1, M2-2, and M2-3.

A selection circuit SC including two vertical transistors Tr1 and Tr2 is located at each of the intersections of the plurality of first word lines M1 and the plurality of second word lines M2. The vertical transistor has a channel formed perpendicular to the principal surface of the substrate.

In the selection circuit SC, the vertical transistors Tr1 and Tr2 are connected in series in a vertical direction. The vertical transistors Tr1 and Tr2 share one source/drain region. FIG. 2 shows a planar shape formed of a p-type semiconductor layer 18 (in which a channel of the transistor Tr2 is formed), a gate insulating film 19, and source/drain regions 16 and 21 which constitute the vertical transistor Tr2.

Description will be given of the specific configuration of the selection circuit SC. FIG. 3 is a sectional view taken along line III-III shown in FIG. 2.

A contact plug V1 is provided above the principal surface of the substrate (not shown). The contact plug V1 constitutes an input section or output section of the selection circuit SC. The selection circuit SC is connected to another circuit, terminal, or the like via the contact plug V1.

A source/drain region (source/drain layer) 11 consisting of an n⁺-type semiconductor layer is provided above the contact plug V1. The source/drain region 11 constitutes a source/drain region of the vertical transistor Tr1. The planar shape (or plan configuration) of the source/drain region 11 is, for example, circular and has a larger diameter than openings in the first word line M1, described later.

The gate electrode (first word line) M1 extending in the X direction is provided above the source/drain region 11. The first word line M1 has, for example, openings that are circular.

An insulating film 12 (formed of, for example, SiO₂) is provided between the source/drain region 11 and the first word line M1. A p-type semiconductor layer 13 is provided on the source/drain region 11 and in the openings in the first word line M1; the p-type semiconductor layer 13 is a base region in which a channel of the vertical transistor Tr1 is formed. A gate insulating film 14 (formed of, for example, SiO₂) is provided between the p-type semiconductor layer 13 and the first word line M1.

A source/drain region 16 consisting of an n⁺-type semiconductor layer is provided on the p-type semiconductor layer 13 and above the first word line M1. The source/drain region 16 constitutes a source/drain region of the vertical transistor Tr1 and a source/drain region of the vertical transistor Tr2. The planar shape of the source/drain region 16 is, for example, circular and has a larger diameter than the openings in the first word line M1.

An insulating film 15 (formed of, for example, SiO₂) is provided between the source/drain region 16 and the first word line M1.

The gate electrode (second word line) M2 is provided above the source/drain region 16. The second word line M2 has openings that are, for example, circular. Each of the openings in the second word line M2 is located at the intersection of the first word line M1 and the second word line M2. Specifically, each opening in the second word line M2 is located immediately above the corresponding opening in the first word line M1.

An insulating film 17 (formed of, for example, SiO₂) is provided between the source/drain region 16 and the second word line M2.

A p-type semiconductor layer 18 is provided on the source/drain region 16 and in the openings in the second word line M2; the p-type semiconductor layer 18 is a base region in which a channel of the vertical transistor Tr2 is formed. A gate insulating film 19 (formed of, for example, SiO₂) is provided between the p-type semiconductor layer 18 and the second word line M2.

A source/drain region 21 consisting of an n⁺-type semiconductor layer is provided on the p-type semiconductor layer 18 and above the second word line M2. The source/drain region 21 constitutes a source/drain region of the vertical transistor Tr2. The planar shape of the source/drain region 16 is, for example, circular and has a larger diameter than the openings in the first word line M2.

An insulating film 20 (formed of, for example, SiO₂) is provided between the source/drain region 21 and the second word line M2. A contact plug V2 is provided above the source/drain region 21. The contact plug V2 constitutes an input section or output section of the selection circuit SC. The selection circuit SC is connected to another circuit, terminal, or the like via the contact plug V2. The periphery of the vertical transistors Tr1 and Tr2 is covered with an interlayer insulating film 22.

Now, with reference to FIGS. 4 to 11, description will be given of an example of a method for manufacturing a semiconductor device configured as described above.

First, as shown in FIG. 4, a contact plug V1 (formed of a metal material such as A1 or W) is formed in an interlayer insulating film 22a (formed of SiO₂), and then an n⁺-type semiconductor layer (source/drain region) 11 is formed on the contact plug V1 and the n⁺-type semiconductor layer 11. The n⁺-type semiconductor layer 11 is formed by depositing silicon doped with phosphorous (P) or arsenic (As) using a sputtering method, a chemical vapor deposition (CVD) method, or the like.

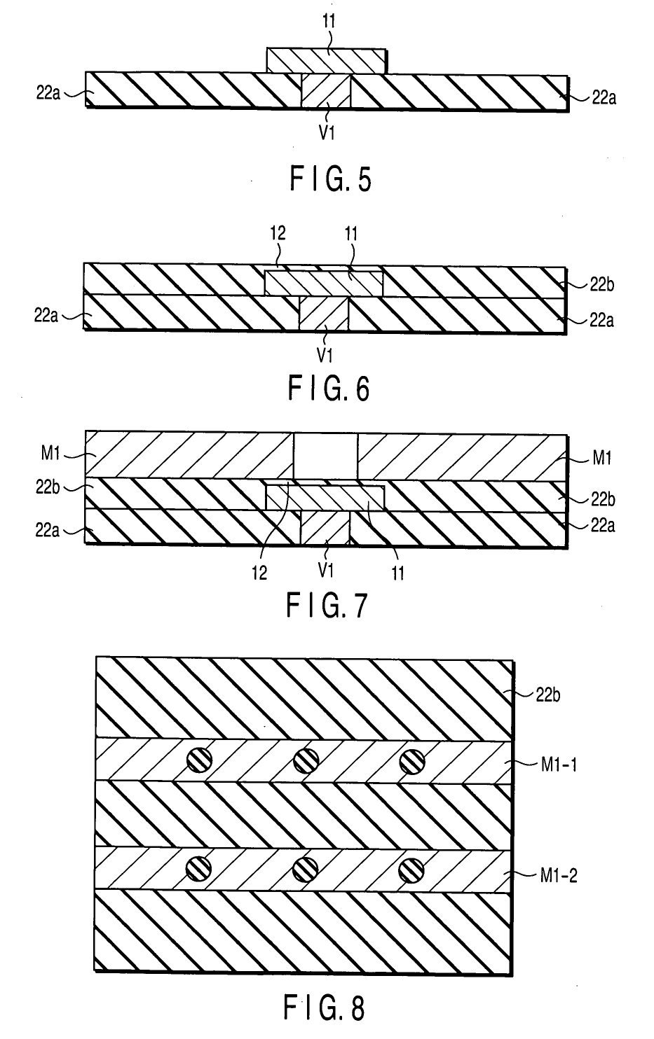

Then, as shown in FIG. 5, the n⁺-type semiconductor layer 11 is patterned by a lithography method to form a source/drain region 11.

Then, as shown in FIG. 6, an interlayer insulating film 22b covering the source/drain region 11 is formed on the interlayer insulating film 22a. The interlayer insulating film 22b is formed by depositing SiO₂ using a plasma CVD method. The surface of the interlayer insulating film 22b is flattened using a chemical mechanical polishing (CMP) method.

On this occasion, SiO₂ is left on the source/drain region 11 so that the source/drain region 11 does not contact the gate electrode (first word line) M1. As a result, an insulating film 12 is formed on the source/drain region 11.

Then, as shown in FIG. 7, a conductive material constituting the gate electrode M1 is deposited on the interlayer insulating film 22b using the sputtering method, CVD method, or the like. The gate electrode M1 is then patterned using the lithography method. At this time, circular openings are formed in the gate electrode M1. The openings are formed above a place in which the source/drain region 11 is buried. FIG. 8 is a plan view showing the patterned gate electrode M1.

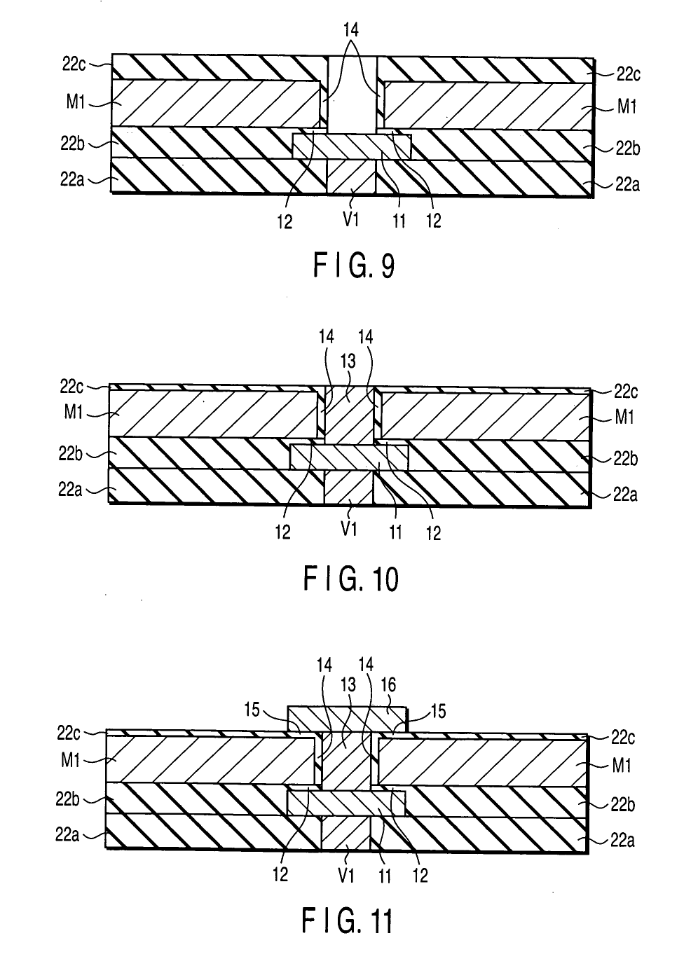

Then, as shown in FIG. 9, an interlayer insulating film 22c (formed of SiO₂) is deposited on the gate electrode M1 and in the openings. The surface of the interlayer insulating film 22c is flattened using the CMP method. Subsequently, in each of the openings in the gate electrode M1, a hole is made in the interlayer insulating film 22c using a reactive ion etching (RIE) method so that the opening reaches the source/drain region 11. At this time, SiO₂ remaining on a sidewall of the opening of the gate electrode M1 is utilized as the gate insulating film 14

Then, as shown in FIG. 10, a p-type semiconductor layer 13 is formed to fill the openings in the gate electrode M1. The p-type semiconductor layer 13 is formed by using the CVD method or the like to deposit Si doped with boron (B). The CMP method is then used to remove excess Si and interlayer insulating film 22c formed in the areas other than the openings. On this occasion, a thin layer of the interlayer insulating film 22c is left on the gate electrode M1 so that the gate electrode M1 does not contact the source/drain region 16. As a result, an insulating film 15 is formed.

Then, an n⁺-type semiconductor layer (source/drain region) 16 is deposited on the p-type semiconductor layer 13. The n⁺-type semiconductor layer 16 is formed by using the sputtering method or the CVD method to deposit Si doped with phosphorous (P) or arsenic (As). The n⁺-type semiconductor layer 16 is patterned by the lithography method to form a source/drain region 16.

Then, the following are formed: a gate electrode (second word line) M2, a p-type semiconductor layer 18, a gate insulating film 19, and a source/drain region 21 which constitute a vertical transistor Tr2. A method for manufacturing these layers is similar to that used for the vertical transistor Tr1.

Subsequently, an opening (not shown) is formed in the interlayer insulating film 22 by the RIE method to expose the source/drain region 21. The opening is filled with a metal material, for example, A1 or W. Unwanted parts of the metal material are removed by, for example, the CMP method to form a contact plug V2 connected to the source/drain region 21. In this manner, the semiconductor device shown in FIG. 3 is formed.

The above method for manufacturing is an example. It is possible to use, for example, a method for manufacturing described in Document 1 (J. M. Hergenrother et al., The vertical replacement-gate (VRG) MOSFET, Solid-State Electronics 46 (2002), p 939-950) or Document 2 (H. Takato et al., High Performance CMOS Surrounding Gate Transistor (SGT) for Ultra High Density LSIs, Tech. Dig. Int. Electron Devices Meet., 1988, p 222).

As described above, according to the present embodiment, by selecting any two word lines extending lengthwise and breadth wise, it is possible to pass a feedthrough current through the selection circuit located at that intersection. That is, only an arbitrary selection circuit can be turned on even if selection circuits are arranged in matrix. The semiconductor device can constitute a desired logic circuit by combining the connections between the input and output sections of a plurality of selection circuits.

The present embodiment is also applicable to a floating body cell (FBC). The FBC is a cell that stores data by accumulating charges in a floating body of a MOS transistor. A semiconductor storage device can be composed of vertical transistors constructed using FBCs. Further, it is possible only to select any one of the plurality of FBCs.

Further, since a semiconductor device is composed of vertical transistors, the circuit area can be reduced compared to that of planar transistors. Moreover, two vertical transistors can be arranged in the vertical direction, thus reducing the circuit area.

Further, the source/drain regions of two selection circuits are composed of the common semiconductor layer. This makes it possible to reduce the number of steps of manufacturing a selection circuit.

In the present embodiment, the semiconductor device is constructed by connecting two n-channel MOS transistors together in series. However, the semiconductor device may be constructed by connecting two p-channel MOS transistors together in series.

Alternatively, the selection circuit may be composed of Schottky transistors having a source/drain region composed of a metal layer. The metal layer may be cobalt silicide (CoSi), platinum silicide (PtSi), or the like. Alternatively, other materials may be used.

The metal layer serving as a source/drain region is formed by depositing Co on an Si layer using the sputtering method and then allowing Si and Co to react with each other using a rapid thermal anneal (RTA) method. This configuration of the selection circuit enables its operating speed to be improved.

(Second Embodiment)

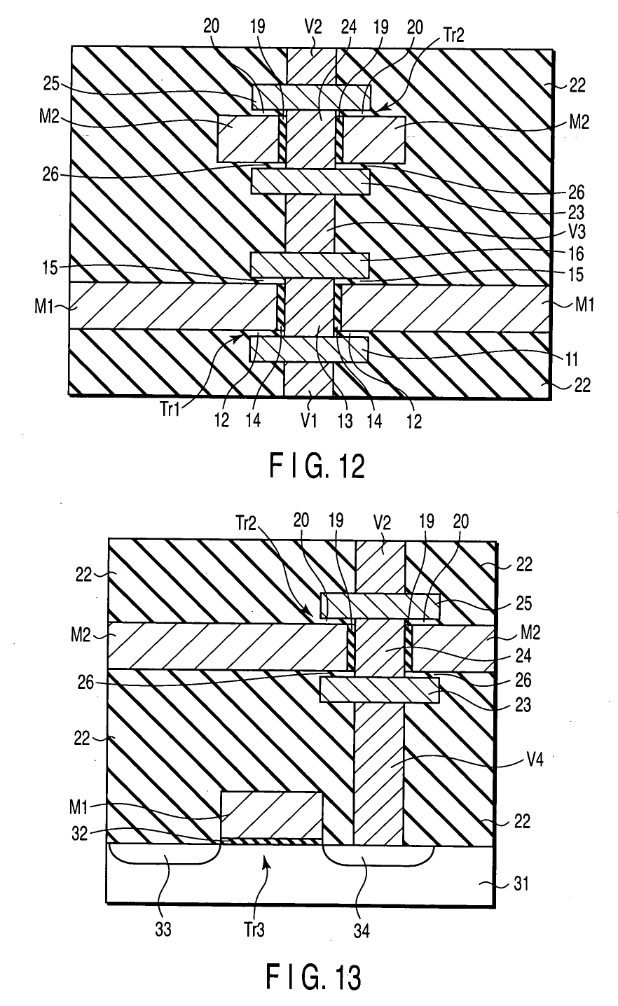

FIG. 12 is a sectional view of a semiconductor device according to a second embodiment of the present invention. The selection circuit SC is composed of the vertical transistors Tr1 and Tr2 connected together in series. The configuration of the vertical transistor Tr1 is the same as that according to the first embodiment.

A contact plug V3 is provided on the source/drain region 16. A source/drain region 23 consisting of a p⁺-type semiconductor layer is provided on the contact plug V3. The source/drain region 23 is composed of Si doped with boron. The planar shape of the source/drain region 23 is, for example, circular, and has a larger diameter than the openings in the second word line M2, described later.

The second word line M2 is provided above the source/drain region 23. The second word line M2 has circular openings. An insulating film 26 is provided between the source/drain region 23 and the second word line M2.

An n-type semiconductor layer 24 is provided on the source/drain region 23 and in the openings in the second word line M2; the n-type semiconductor layer 24 is a base region in which the channel of the vertical transistor Tr2 is formed. The n-type semiconductor layer 24 is composed of Si doped with phosphorous (P) or arsenic (As). The gate insulating film 19 is provided between the n-type semiconductor layer 24 and the second word line M2.

A source/drain region 25 consisting of a p⁺-type semiconductor layer is provided on the n-type semiconductor layer 24 and above the second word line M2. The p⁺-type semiconductor layer is composed of Si doped with phosphorous (P) or arsenic (As).

This configuration allows the selection circuit SC to be composed of an n-channel MOS transistor and a p-channel MOS transistor. That is, a current can be passed through the selection circuit SC by setting the first word line M1 at the high level, while setting the second word line M2 at the low level.

The vertical transistor Tr1, placed in the lower part of the selection circuit SC, may be composed of a p-channel MOS transistor. The vertical transistor Tr2, placed in the upper part of the selection circuit SC, may be composed of an n-channel MOS transistor.

Further, the two vertical transistors may both be composed of n-channel MOS transistors. Alternatively, the two vertical transistors may both be composed of p-channel MOS transistors.

Alternatively, the vertical transistor may be composed of Schottky transistors as in the case of the first embodiment.

(Third Embodiment)

According to a third embodiment, a planar transistor and a vertical transistor are used as the two transistors constituting the selection circuit.

FIG. 13 is a sectional view of a semiconductor device according to a third embodiment of the present invention. A planar transistor Tr3 is formed on a surface area of an n-type semiconductor substrate formed of, for example, Si.

The planar transistor Tr3 is composed of a gate insulating film 32 formed of, for example, SiO₂, the gate electrode (first word line) M1 formed on the gate insulating film 32, sidewall insulating films (not shown) formed on the opposite sidewalls of the gate electrode, and source/drain regions (p⁺-type diffusion layers) 33 and 34 formed in the n-type semiconductor substrate 31.

A contact plug V4 is provided on the source/drain region 34. The vertical transistor Tr2 is provided on the contact plug V4. The second word line M2 is placed perpendicularly to the direction in which the first word line M1. The vertical transistor Tr2 has the same configuration as that of the vertical transistor Tr2, shown in the second embodiment.

This configuration of the semiconductor device exerts effects similar to those of the first and second embodiments. In the present embodiment, the semiconductor device is composed of the two p-channel MOS transistors connected together in series. However, the semiconductor device may be composed of two n-channel MOS transistors. Alternatively, the two transistors may be composed of an n-channel MOS transistor and a p-channel MOS transistor.

In the above embodiments, circular shapes are provided for the openings in the first word line M1 and second word line as well as the source/drain regions. However, the present invention is not limited to this. These components may have other shapes such as rectangles.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a plurality of first word lines which extend in a first direction;
a plurality of second word lines which extend in a direction orthogonal to the first direction;
a plurality of selection circuits which are provided at intersections of the first word lines and the second word lines, and each of which includes a first transistor and a second transistor which are connected in series, the first transistor having a gate electrode connected to one of the first word lines, and the second transistor having a gate electrode connected to one of the second word lines.

2. The semiconductor device according to claim 1, wherein, when one first word line and one second word line are activated, only the selection circuit connected to the first word line and the second word line is activated.

3. A semiconductor device comprising:
a first source/drain layer;
a first gate electrode provided above the first source/drain layer so as to extend in a first direction and having a first opening;
a first gate insulating film provided so as to cover a side surface of the first opening;
a first base layer provided on the first source/drain layer and on a side surface of the first gate insulating film and being of a first conductivity type;
a second source/drain layer provided above the first gate electrode and on the first base layer;
a second gate electrode provided above the second source/drain layer so as to extend in a direction orthogonal to the first direction and having a second opening;
a second gate insulating film provided so as to cover a side surface of the second opening;
a second base layer provided on the second source/drain layer and on a side surface of the second gate insulating film and being of the first conductivity type; and
a third source/drain layer provided above the second gate electrode and on the second base layer.

4. The semiconductor device according to claim 3, wherein the first to third source/drain layers are of a second conductivity type.

5. The semiconductor device according to claim 3, wherein the first to third source/drain layers are formed of a metal, and
the first and second base layers are semiconductor layers.

6. The semiconductor device according to claim 3, further comprising:
a first insulating film provided between the first source/drain layer and the first gate electrode;
a second insulating film provided between the first gate electrode and the second source/drain layer;
a third insulating film provided between the second source/drain layer and the second gate electrode; and
a fourth insulating film provided between the second gate electrode and the third source/drain layer.

7. The semiconductor device according to claim 3, wherein the first and second openings are formed at a intersection of the first gate electrode and the second gate electrode.

8. The semiconductor device according to claim 3, wherein the first opening is formed in a direction perpendicular to a principal surface of the first gate electrode, and
the second opening is formed in the direction perpendicular to the principal surface of the first gate electrode.

9. The semiconductor device according to claim 3, wherein the first and second openings are circular.

10. The semiconductor device according to claim 3, wherein planar shapes of the first to third source/drain layers are circular.

11. A semiconductor device comprising:
a first source/drain layer;
a first gate electrode provided above the first source/drain layer so as to extend in a first direction and having a first opening;
a first gate insulating film provided so as to cover a side surface of the first opening;
a first base layer provided on the first source/drain layer and on a side surface of the first gate insulating film;
a second source/drain layer provided above the first gate electrode and on the first base layer;
a contact layer provided on the second source/drain layer;
a third source/drain layer provided on the contact layer;
a second gate electrode provided above the third source/drain layer so as to extend in a direction orthogonal to the first direction and having a second opening;
a second gate insulating film provided so as to cover a side surface of the second opening;
a second base layer provided on the third source/drain layer and on a side surface of the second gate insulating film; and
a fourth source/drain layer provided above the second gate electrode and on the second base layer.

12. The semiconductor device according to claim 11, wherein the first and second base layers are of a first conductivity type, and
the first to fourth source/drain layers are of a second conductivity type.

13. The semiconductor device according to claim 11, wherein the first source/drain layer, the second source/drain layer, and the second base layer are of a first conductivity type, and
the third source/drain layer, the fourth source/drain layer, and the first base layer are of a second conductivity type.

14. The semiconductor device according to claim 11, wherein the first to fourth source/drain layers are formed of a metal, and
the first and second base layers are semiconductor layers.

15. The semiconductor device according to claim 11, further comprising:
a first insulating film provided between the first source/drain layer and the first gate electrode;
a second insulating film provided between the first gate electrode and the second source/drain layer;
a third insulating film provided between the third source/drain layer and the second gate electrode; and
a fourth insulating film provided between the second gate electrode and the fourth source/drain layer.

16. The semiconductor device according to claim 11, wherein the first and second openings are formed at a intersection of the first gate electrode and the second gate electrode.

17. The semiconductor device according to claim 11, wherein the first opening is formed in a direction perpendicular to a principal surface of the first gate electrode, and
the second opening is formed in the direction perpendicular to the principal surface of the first gate electrode.

18. A semiconductor device comprising:
a semiconductor substrate;
a first gate electrode provided on the semiconductor substrate via a first gate insulating film so as to extend in a first direction;
a first and second source/drain layers provided on opposite sides of the first gate electrode and in the semiconductor substrate;
a contact layer provided on the first source/drain layer;
a third source/drain layer provided on the contact layer;
a second gate electrode provided above the third source/drain layer so as to extend in a direction orthogonal to the first direction and having a opening;
a second gate insulating film provided so as to cover a side surface of the opening;
a base layer provided on the third source/drain layer and on a side surface of the second gate insulating film; and
a fourth source/drain layer provided above the second gate electrode and on the base layer.

19. The semiconductor device according to claim 18, wherein the semiconductor substrate and the base layer are of a first conductivity type, and
the first to fourth source/drain layers are of a second conductivity type.

20. The semiconductor device according to claim 18, wherein the first to fourth source/drain layers are formed of a metal, and
the base layer is a semiconductor layer.
